(19) United States
(12) Patent Application Publication
(10) Pub. No.: US 2024/0280901 A1
(43) Pub. Date: Aug. 22, 2024

(54) PHOTORESIST COMPOSITION AND USE THEREOF

(71) Applicant: THE INSTITUTE OF OPTICS AND ELECTRONICS, THE CHINESE ACADEMY OF SCIENCES, Sichuan (CN)

(72) Inventors: Xiangang LUO, Sichuan (CN); Dongxu YANG, Sichuan (CN); Xian PENG, Sichuan (CN); Kaixin SU, Sichuan (CN); Zeyu ZHAO, Sichuan (CN); Ping GAO, Sichuan (CN); Changtao WANG, Sichuan (CN)

(21) Appl. No.: 18/575,625

(22) PCT Filed: Nov. 3, 2022
(86) PCT No.: PCT/CN2022/129511

§ 371 Date: Dec. 29, 2023

(30) Foreign Application Priority Data
Dec. 10, 2021 (CN) 202111513743.5

(51) Int. Cl. G03F 7/004; G03F 7/039

(52) U.S. Cl. CPC G03F 7/0045; G03F 7/0392

(57) ABSTRACT

A photoresist composition is provided, including a chemical amplification matrix, wherein the chemical amplification matrix includes a polymer resin, a photoacid generator and a solvent; and a dissolution inhibitor, which is a small molecular material containing a diazo naphthoquinone structure. A method for using the photoresist composition is further provided.

The present disclosure claims priority to Chinese Patent Application No. 202111513743.5 filed on Dec. 10, 2021, which is incorporated herein by reference in its entirety.

### TECHNICAL FIELD

The present disclosure relates to the technical field of photoresists, in particular to a photoresist composition and use thereof.

### BACKGROUND

Resolution is a prerequisite for determining optical lithographic performance. The conventional projection lithography is influenced by diffraction limit, and the ultimate resolution is limited within the range of ½-¼ wavelength. Further improvement in the resolution level requires continuous shortening of a light source wavelength and increase of a numerical aperture. However, this route is accompanied by a sharp increase in technical difficulty and cost. The current top-level extreme ultra-violet (EUV) lithography approaches the limit of this development route in the aspects of equipment manufacturing cost, engineering technology and lithography materials.

In order to break through the bottleneck of the conventional resolution diffraction limit, researchers have proposed a variety of novel optical lithography techniques in recent years, such as two-photon absorption lithography based on femtosecond laser technology, fluorescence super-resolution lithography based on excitation radiation suppression, and SP super-diffraction lithography based on surface plasma excitation. These technologies are expected to replace the conventional projection lithography and become a new generation of nanolithography technologies with a low cost, high efficiency and a large area.

However, the specific photoresist materials used in the novel lithography technology are rarely reported in the literatures or patents. As research work, the materials used for the verification of the novel high-resolution lithography technology are almost all commercial photoresists. The current high-resolution photoresist usually requires nanoscale (100 nm or less) resolution, which resolution requires an ultrathin photoresist film layer to prevent collapse of a nanometer pattern, and targeted optimization of the main resin molecules, photosensitive materials, additive components, and the like; however, the conventional commercial photoresist corresponding to the wavelength often cannot meet the requirement. For example, for the I-line (with a wavelength of 365 nm) nanoscale lithography technology, the conventional commercial I-line photoresist is optimized based on a micrometer-scale thickness and resolution greater than 350 nm, so it is difficult to be directly used for verification of the nanoscale resolution lithography, and the commercial deep ultraviolet photoresist with higher resolution usually does not have enough photosensitivity in the near ultraviolet band.

Therefore, for the emerging technologies such as ultrahigh resolution optical lithography, the existing photoresist materials are difficult to match the technical verification and process development thereof, and the new photoresist materials need to be developed in a targeted manner.

### SUMMARY

### (1) Technical Problems to be Resolved

In order to solve the above problems, the present disclosure provides a photoresist composition and use thereof, which are used to solve the technical problems that the conventional photoresist is difficult to realize an ultrathin photoresist film layer and achieve ultrahigh resolution.

### (2) Technical Solutions

In one aspect, the present disclosure provides a photoresist composition, including: a chemical amplification matrix, where the chemical amplification matrix includes a polymer resin, a photoacid generator and a solvent; and a dissolution inhibitor, which is a small molecular material containing a diazonaphthoquinone (DNQ) structure.

Further, the polymer resin is p-hydroxystyrene resin, acrylate resin or a resin obtained by copolymerizing p-hydroxystyrene monomers and acrylate monomers.

Further, the polymer resin contains repeating units of acid labile group.

Further, the polymer resin has a molecular weight of 2000-100000; and the polymer resin is 0.5-10% by weight of the photoresist composition.

Further, the dissolution inhibitor is a molecule including a group containing 2 to 10 diazonaphthoquinone structures, with the group grafted in the form of sulfonate ester on a polyphenol backbone structure containing 2 to 10 phenolic hydroxyl groups.

Further, the dissolution inhibitor has a structure as shown in the following formula III to formula VI:

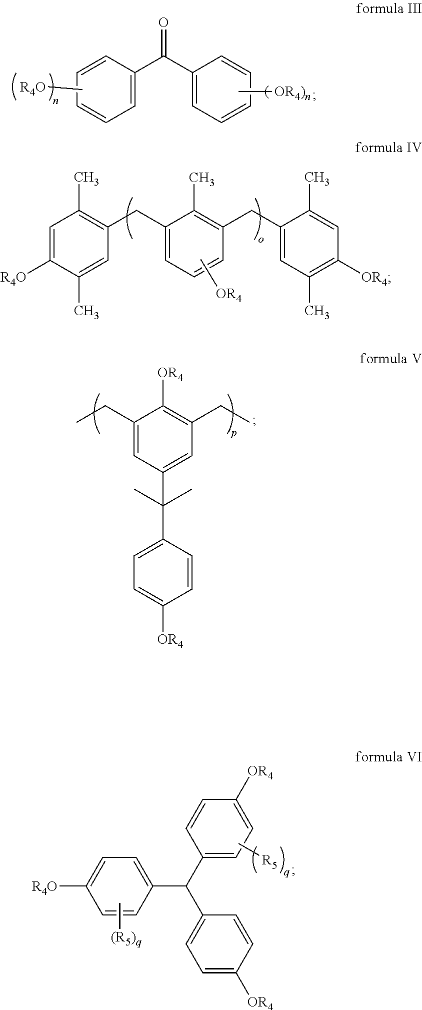

where R₄═H,

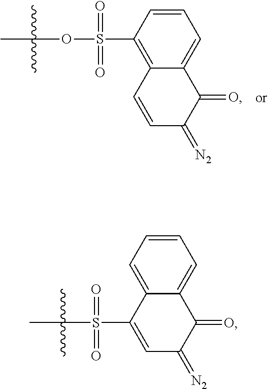

but not all R₄ are H; R₅=alkyl group having 1 to 5 carbon atoms; n=1-5; 0=1-10; p=1-10; and q=0-4.

Further, the dissolution inhibitor is 0.1%-3% by weight of the photoresist composition.

Further, the photoacid generator is a compound of a nonionic sulfonate ester structure or an ionic onium salt structure; and the photoacid generator is 0.1%-5% by weight of the photoresist composition.

Further, the solvent includes one of n-butyl acetate, ethyl acetate, γ-butyrolactone, propylene glycol methyl ether acetate, and propylene glycol methyl ether, or a mixture of more of them.

Further, the solvent is 80-99% by weight of the photoresist composition.

Further, the photoresist composition further includes one of a leveling agent, a surfactant, and a stabilizer, or a mixture of more of them.

In another aspect, the present disclosure provides use of the aforementioned photoresist composition in high-resolution interference lithography, SP super-diffraction lithography, electron beam direct writing, or I-line proximity lithography.

### (3) Beneficial Effects

By creatively introducing a molecule containing diazonaphthoquinone (DNQ) group into a chemically amplified resist system, and utilizing the dissolution inhibiting effect of the DNQ group on hydrophilic groups such as hydroxyl and carboxyl and the characteristic that the DNQ group can be decomposed under illumination and converted in polarity, the photoresist composition according to the present disclosure generates the dissolution inhibiting effect in a non-exposure area and generate the dissolution promoting effect in an exposure area, so that the photoresist composition meets the requirement of high film retention rate under an ultrathin film layer, and the dissolution rate difference of the exposure area/the non-exposure area can be remarkably improved, thereby improving the contrast. Further, the photoresist composition can improve the overall performances of the chemically amplified photoresist composition, such as film retention rate, contrast, resolution, and sensitivity simultaneously, rather than merely making a simple balance between individual performance indexes.

### BRIEF DESCRIPTION OF DRAWINGS

FIG. 1 schematically shows a schematic diagram of the reaction after addition of a dissolution inhibitor to a chemically amplified resist system according to embodiments of the present disclosure;

FIG. 2 schematically shows an exposure result pattern according to Example 1 of the present disclosure;

FIG. 3 schematically shows an exposure result pattern according to Example 5 of the present disclosure; and

FIG. 4 schematically shows an exposure result pattern according to Comparative Example 1 of the present disclosure.

### DETAILED DESCRIPTION OF EMBODIMENTS

In order to make the objectives, technical solutions and advantages of the present disclosure clearer and more understandable, the present disclosure is further described in detail below with reference to the drawings and in conjunction with the specific embodiments.

The terms used herein are for the purpose of describing specific embodiments only and is not intended to limit the present disclosure. The terms “comprise”, “contain”, and the like, as used herein, specify the presence of stated features, steps, operations, and/or components, but do not preclude the presence or addition of one or more other features, steps, operations, or components.

All terms (including technical and scientific terms) used herein have the same meaning as commonly understood by those of ordinary skill in the art, unless otherwise defined. It should be noted that the terms used herein should be interpreted as having a meaning that is consistent with the context of this specification and should not be interpreted in an idealized or overly formal manner.

The present disclosure specifically belongs to the field of photoresist preparation in semiconductor integrated circuit fabrication, and particularly relates to a photoresist composition suitable for a lithography technique with nanoscale resolution, and a method for using the same. The problem to be resolved by the present disclosure is to obtain a photoresist composition suitable for high-resolution lithography, and use thereof and a lithography method therefor, which have nanoscale (100 nm or less) ultrahigh resolution, can form an ultrathin film layer, and are suitable for non-conventional high-resolution lithography technology, especially for near-field ultraviolet nanolithography under the 365 nm I line.

An embodiment of the present disclosure provides a photoresist composition, including: a chemical amplification matrix, where the chemical amplification matrix includes a polymer resin, a photoacid generator and a solvent; and a dissolution inhibitor, which is a small molecular material containing a diazonaphthoquinone structure.

The photoresist composition according to the present disclosure belongs to a chemically amplified resist system, namely, a photoacid generator in the photoresist composition can generate photoacid molecules under the photoinitiation action of a specific wavelength, the photoacid molecules, as a catalyst, can promote reaction to rapidly proceed or initiate a chain reaction, to change the dissolution property of main resin, so as to generate an image through development. The chemical amplification matrix may have both higher resolution and sensitivity. A high-quality nanopattern can be obtained, and thus it is an ideal system for realizing high-resolution lithography.

In the present disclosure, a dissolution inhibitor is added based on the conventional chemically amplified resist system, namely, a small molecule material containing a DNQ structure is added into the chemical amplification matrix of the present disclosure. The small molecule material containing the DNQ structure is usually used as a photosensitive component in a conventional non-chemically amplified photoresist system such as a phenolic resin system. However, the present disclosure creatively adds a small amount of small molecular material containing the DNQ group into the chemical amplification matrix, and utilizes the dissolution inhibiting effect of the DNQ group on hydrophilic groups such as hydroxyl and carboxyl and the characteristic that the DNQ group can be decomposed under illumination and converted in polarity, to generate the dissolution inhibiting effect in a non-exposure area and generate the dissolution promoting effect in an exposure area, so that the obtained photoresist composition can meet the requirement of high film retention rate under an ultrathin film layer, and the dissolution rate difference of the exposure area/the non-exposure area can be remarkably improved, thereby improving the contrast. Also unexpectedly, compared with the conventional dissolution inhibitor solutions, the present disclosure has great advantages in improving resolution, line edge roughness, and sensitivity.

The following formula VII is a reaction mechanism of a typical conventional chemically amplified photoresist system, the main resin of which is poly-p-hydroxystyrene partially protected by tert-butylcarbonyl groups (PBOCST). The photoacids, generated by a photoacid generator (PAG) under illumination or irradiation of electron beam, catalyze a leaving reaction of a protecting group under a heating condition, to generate poly-p-hydroxystyrene (PHOST), thereby making it converted from hydrophobic to hydrophilic.

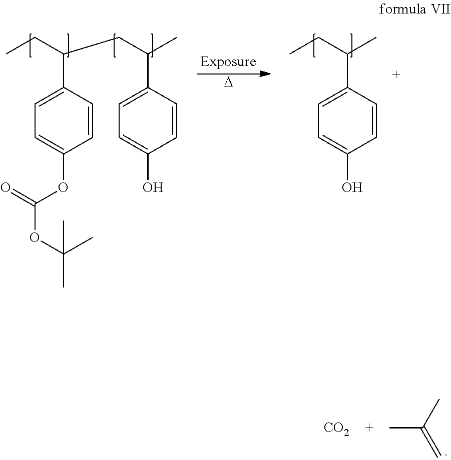

Further, in the non-exposure area, the dissolution inhibitor per se adopted by the present disclosure has strong hydrophobicity and can form intermolecular hydrogen bond with hydroxyl in the resin, so that the dissolution of the photoresist composition in an aqueous alkaline developing solution is inhibited; and in the exposure area, the DNQ part of the dissolution inhibitor is converted into carboxyl group by non-chemical amplification, the action of hydrogen bond disappears, and meanwhile, the photoacid generator generates acids to remove the protecting groups on the side chain of the protecting polymer by chemical amplification to generate polarity conversion, and the superposition effects of the non-chemical amplification and the chemical amplification enable the solubility in the exposure area to be remarkably increased.

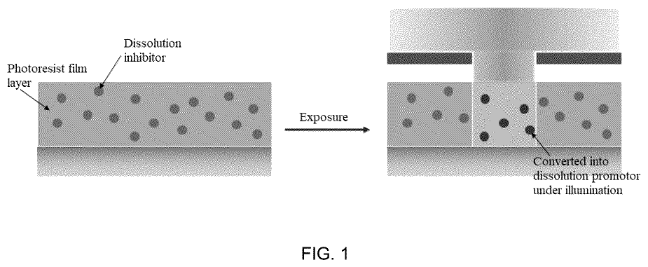

Formula VII and FIG. 1 are a reaction mechanism and a reaction schematic diagram of the present disclosure after the addition of a dissolution inhibitor to the chemical amplification matrix. For the non-exposure area, the diazonaphthoquinone component may interact with the phenolic hydroxyl group through hydrogen bonds, effectively inhibiting the dissolution of the main resin. For the exposure area, diazonaphthoquinone is decomposed under irradiation to generate indancarboxylic acid, so that not only the inhibition effect is eliminated, but also the dissolution of the exposure area can be further promoted due to the high solubility of the carboxylic acid in an alkaline developing solution, thus increasing the chemical contrast of the exposure area and the non-exposure area, and realizing joint improvement of the sensitivity, contrast, and resolution of lithography.

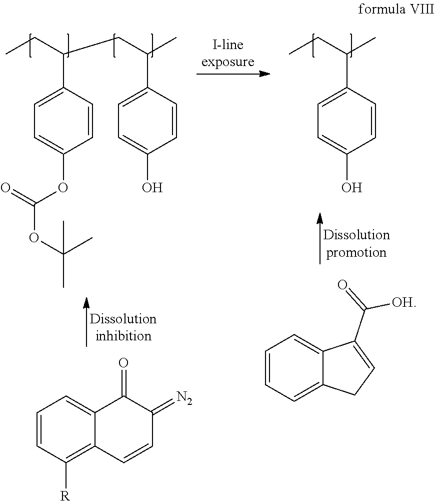

Based on the above examples, the polymer resin is a p-hydroxystyrene resin, an acrylate resin or a resin obtained by copolymerizing p-hydroxystyrene monomers and acrylate monomers.

The polymer resin may be a p-hydroxystyrene resin, an acrylate resin, or a copolymer resin containing the p-hydroxystyrene resin and the acrylate resin. The monomer type of the polymer resin conforms to at least one of the general chemical formulas (I) and (II).

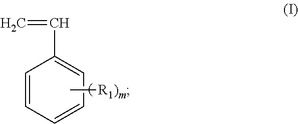

in this formula: R₁═H, OH, alkyl or alkoxy having 1-20 carbon atoms, ester having 1-20 carbon atoms, and/or a hydroxyl group at least partially protected by structure of tert-butyloxycarbonyl, vinyl, adamantane, acetal, ether, or the like.

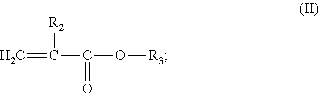

in this formula: R₂ is hydrogen or methyl; R₃ is H, alkyl having 1 to 20 carbon atoms, cycloalkyl having 3 to 8 carbon atoms or hydroxyalkyl having 1 to 20 carbon atoms. Of course, the polymer resin is not limited to only the poly-p-hydroxystyrene and the acrylate resin. Practically, the resins suitable for a chemically amplified resist system are all suitable for the photoresist composition of the present disclosure.

Based on the above examples, the polymer resin contains repeating units of an acid labile group.

The repeating units of the acid labile group include, for example, a structure having an ester, a structure having an acetal, and the like. The acid labile group can promote the reaction to rapidly proceed or initiate a chain reaction under the action of photoacids generated by PAG; and as shown in formula VIII, DNQ has the effects, on such polymer resin, of effectively inhibiting dissolution in non-exposure areas and promoting dissolution in exposure areas, so that the chemical contrast of the exposure areas and the non-exposure areas is increased.

Based on the above examples, the polymer resin has a molecular weight of 2000-100000; and the polymer resin is 0.5-10% by weight of the photoresist composition.

The polymer resin is a polymer resin based on an acid catalyzed deprotection mechanism, and has a molecular weight of 2000-100000, and a molecular weight distribution coefficient Mw/Mn of 1.1-2.0. It should be noted that unlike the thicker film layer used in the current commercial photoresist, for the film layer used to satisfy the high resolution, due to the extremely small thickness, the small loss of the film thickness during the development process can result in the disappearance of the pattern or the deterioration of the effect (the thickness loss should be <2 nm/30 s (2.38% TMAH)).

Therefore, the polymer resin used in the present disclosure has a moderate molecular weight, and too small molecules may make the photoresist composition easily soluble in an aqueous alkaline developing solution, resulting in an insufficient film retention rate, and meanwhile, the molecules should not be too large, otherwise the resolution and roughness will be affected. The polymer resin selected in the present disclosure can be actually any polymer resin suitable for use in chemically amplified photoresist systems, but is preferably a poly-p-hydroxystyrene resin or a copolymer resin of p-hydroxystyrene and acrylate. In the present disclosure, the polymer resin may be 0.5-10%, preferably 1-8%, and more preferably 3-5%, by weight of the photoresist composition.

Based on the above examples, the dissolution inhibitor is a molecule including a group containing 2 to 10 diazonaphthoquinone structures, with the group grafted in the form of sulfonate ester on a polyphenol backbone structure containing 2 to 10 phenolic hydroxyl groups.

The dissolution inhibitor is a small molecular material containing diazonaphthoquinone structures, such as 2,1,4-diazonaphthoquinone sulfonate, 2,1,5-diazonaphthoquinone sulfonate; the 2,1,4-diazonaphthoquinone sulfonate and 2,1,5-diazonaphthoquinone sulfonate are grafted on the polyphenol backbone structure of the phenolic hydroxyl groups.

Based on the above examples, the dissolution inhibitor has a structure as shown in the following formula III to formula VI:

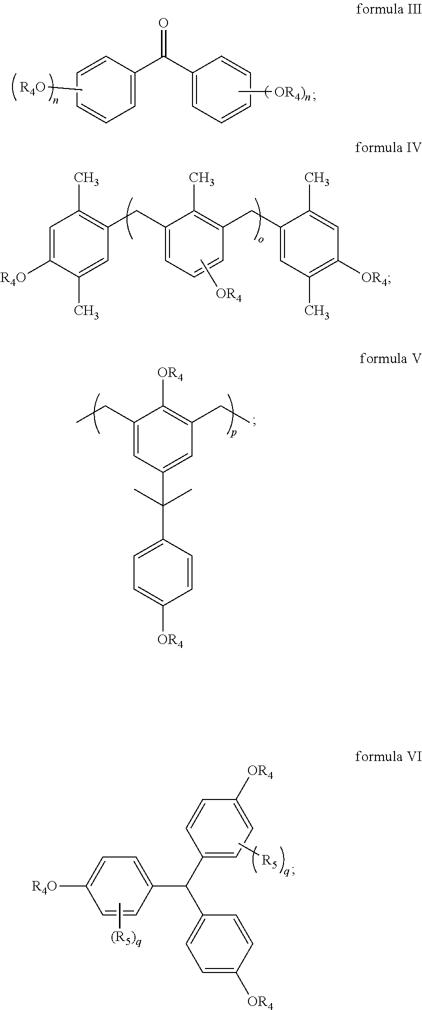

where R₄═H,

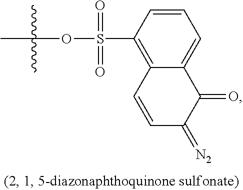

or

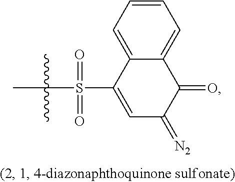

however, not all R₄ are H; R₅=alkyl group having 1 to 5 carbon atoms; n=1-5; 0=1-10; p=1-10; and q=0-4.

Of course, the dissolution inhibitor is not limited to the compound with the above structural formula, and diazonaphthoquinone small molecule materials with other structures may also be applied as the dissolution inhibitor in the photoresist composition of the present disclosure.

Based on the above examples, the dissolution inhibitor is 0.1%-3% by weight of the photoresist composition.

The addition of too much dissolution inhibitor may result in too strong hydrophobicity of the film layer and solubility switching is dominated by the inhibitor rather than PAG, then affecting the pattern quality; and the addition of too little dissolution inhibitor results in insignificant effects thereof of inhibiting the dissolution in the non-exposure areas and promoting the dissolution in the exposure areas. Therefore, the dissolution inhibitor is 0.1%-3%, preferably 0.5-2%, by weight of the photoresist composition.

Based on the above examples, the photoacid generator is a compound of a nonionic sulfonate ester structure or an ionic onium salt structure; and the photoacid generator is 0.1%-5% by weight of the photoresist composition.

A photoacid generator (PAG) generates an acid (called photoacid) when irradiated with light of a specific wavelength, and the photoacid catalyzes a deprotection reaction of an exposed part of the photoresist (as shown in formula VII) at a certain temperature, so that the exposed part may be dissolved upon development to generate an image. In fact, the PAG selected in the present disclosure may be any photoacid generator that can be used in chemically amplified resist system, and preferably is a PAG of a nonionic sulfonate structure and a PAG of an ionic onium salt structure. In the present disclosure, the PAG may be 0.1%-5%, preferably 0.5%-3%, by weight of the photoresist composition.

Based on the above examples, the solvent is one of n-butyl acetate, ethyl acetate, γ-butyrolactone, propylene glycol methyl ether acetate, and propylene glycol methyl ether, or a mixture of more of them.

The solvent may make the photoresist in a liquid state to facilitate coating, and other components are mixed by the solvent to form the photoresist composition. The solvent used in the present disclosure may be a component selected from n-butyl acetate, ethyl acetate, γ-butyrolactone, propylene glycol methyl ether acetate (PGMEA), propylene glycol methyl ether, and a mixture of them, which solvent has good coverage for dissolving multiple photoresist components of different polarities.

Based on the above examples, the solvent is 80-99% by weight of the photoresist composition.

In the present disclosure, the solvent may be 80-99%, preferably 90-98%, and more preferably 92-96%, by weight of the photoresist composition. The solvent ratio is based on an optimized value for forming an ultrathin film layer of 100 nm or less. It is difficult to form the ultrathin film layer by means of spin coating (the spin coating speed is 1500-4000 rpm), when the solvent is too little, and it is difficult to form a high-quality photoresist film layer, when the solvent is too much and the photoresist is too thin.

Based on the above examples, the photoresist composition further includes one of a leveling agent, a surfactant, and a stabilizer, or a mixture of more of them.

The photoresist composition according to the present disclosure may also be optionally added with small amount (within 1% of the total content) of the leveling agent, the surfactant, the stabilizer and the like, including but not limited to any one or more of small molecule amines, siloxanes, ethylene/propylene oxides, and fluorine-containing alkane molecules.

For the photoresist composition provided by the present disclosure, by adding the dissolution inhibitor with specific functional groups, an ultrathin photoresist film layer with a high film retention rate (the film thickness is 100 nm or less, the thickness loss of a non-exposure area is <2 nm/30 s) may be realized, meanwhile, the chemical contrast of the exposure area and the non-exposure area is increased, realizing joint improvement of the sensitivity, contrast and resolution of lithography. The photoresist composition is particularly suitable for the fields of high-resolution optical lithography and electron beam lithography with a wavelength of 150-450 nm, and can realize the preparation of a dense line pattern with a size of less than 64 nm.

The present disclosure further provides use of the aforementioned photoresist composition in high-resolution interference lithography, near field lithography, SP super-diffraction lithography, electron beam direct writing, or I-line proximity lithography.

The photoresist composition in the present disclosure can not only be used in conventional I-line ultraviolet lithography, but also be used in novel high-resolution lithography, such as high-resolution interference lithography, SP super-diffraction lithography and electron beam direct writing. The requirements on the thickness and resolution of the photoresist film layer in the above fields are usually much higher than those of the existing near ultraviolet and deep ultraviolet lithography. Even for a photoresist such as EUV lithography, which also uses an ultrathin film layer, it is difficult to directly apply it to the above novel lithography technique due to the mismatch in photosensitive wavelength.

In summary, the component combination of chemically amplified photoresist proposed in the present disclosure, particularly the employment of the strategy of introducing a dissolution inhibitor, is a technical idea not possessed by conventional chemically amplified photoresist system. For the lithography pattern quality, the strategy can simultaneously improve the overall performances of the chemically amplified photoresist, such as film retention rate, contrast, resolution, and sensitivity, and is more than making a simple balance between individual performance indexes.

Therefore, the solution of the present disclosure is particularly suitable for novel high-resolution (100 nm or less) lithography technique. For the photoresist film layer, the photoresist composition provided by the present disclosure is suitable for an ultrathin photoresist film layer (100 nm or below), which is also matched with the requirement of high resolution above. However, the conventional commercial photoresist material generally has the problem of insufficient film retention rate under the ultrathin film layer.

The present disclosure will be further described below through specific embodiments. The above photoresist composition and use thereof are specifically described in the following examples. However, the following examples are only for illustrating the present disclosure, and the scope of the present disclosure is not limited thereto.

The photoresist composition of the present disclosure includes a polymer resin, a photoacid generator, a dissolution inhibitor, a solvent, and other additive components including a leveling agent, a surfactant, a stabilizer, and the like. The photoresist material provided by the present disclosure is suitable for optical lithography technologies with an irradiation wavelength of 150-450 nm (especially super resolution lithography based on 365 nm) requiring an ultrathin film layer of 100 nm or less (preferably 50 nm or less), a high film retention rate (<2 nm/30 s@2.38% TMAH), and high resolution (100 nm or less), such as high-resolution interference lithography, near field lithography, SP super-diffraction lithography, and electron beam direct writing.
1. The polymer resins of the examples and comparative examples include:
(1) a copolymer resin of p-hydroxystyrene and acrylate, having a structural formula as follows:

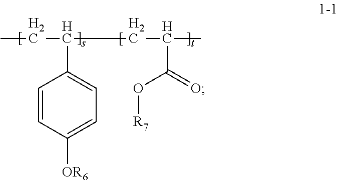

where R₆═H or tert-butylcarbonyl; R₇═H or alkyl;
it may specifically be:

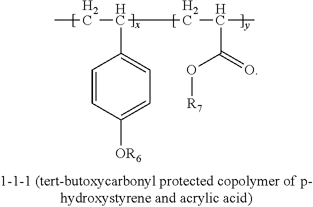

(2) p-hydroxystyrene resin, having a structural formula as follows:

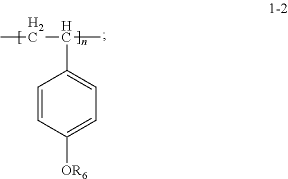

where R₆═H or tert-butoxycarbonyl;
it may specifically be:

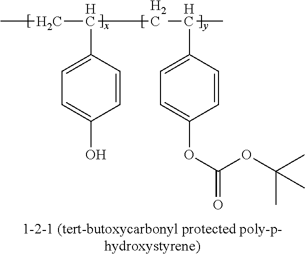 [SMILES: CCC(CC(C)c1ccc(OC(=O)OC(C)(C)C)cc1)c1ccc(O)cc1]

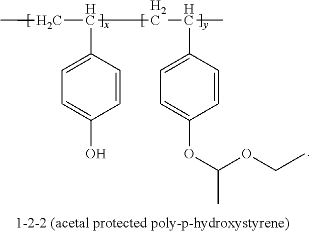 [SMILES: CCOC(C)Oc1ccc(C(C)CC(CC)c2ccc(O)cc2)cc1]

(3) acrylate resin, having a structural formula as follows:

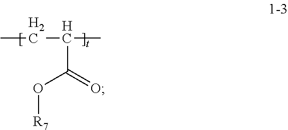

where R₇═H or alkyl;
it may specifically be:

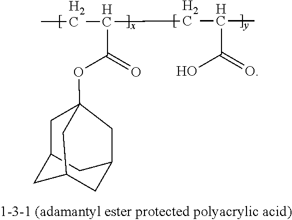 [SMILES: CCC(CC(C)C(=O)O)C(=O)OC12CC3CC(CC(C3)C1)C2]

2. The photoacid generators of the examples and comparative examples include:
(1) a nonionic sulfonate photoacid generator, having a structural formula as follows:

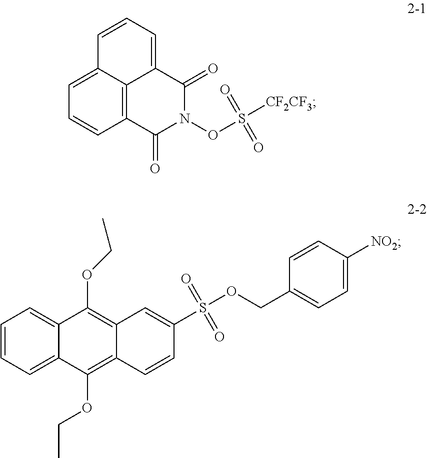

(2) an ionic onium salt photoacid generator, having a structural formula as follows:

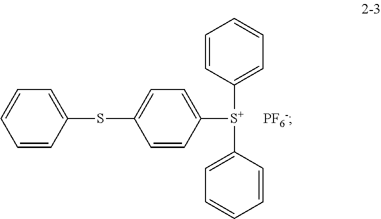

3. The dissolution inhibitors of the examples and comparative examples have structural formulas as follows:

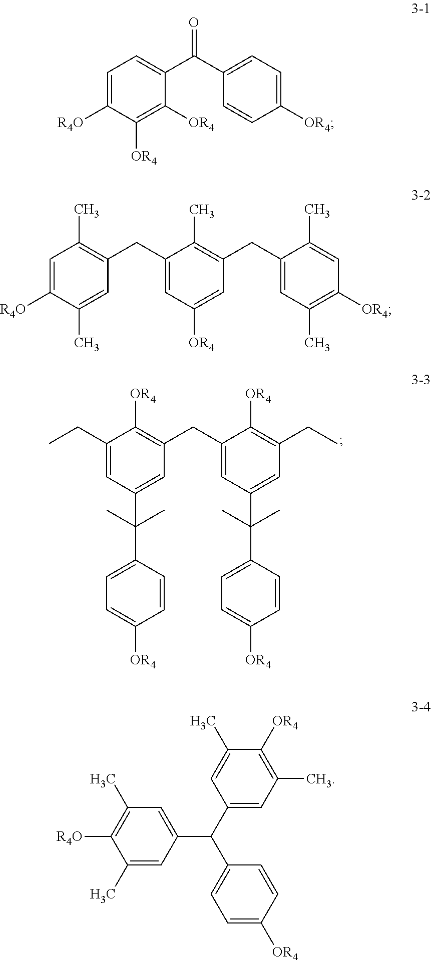

In the 3-1 and 3-3, three of the R₄ are

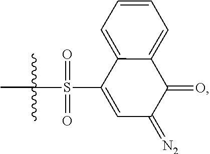

and the other one R₄ is H. In the 3-2 and 3-4, all the R₄ are

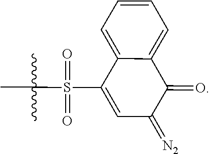

4. The solvents of the examples and comparative examples include propylene glycol methyl ether acetate (4-1), ethyl lactate (4-2), and propylene glycol monomethyl ether (4-3).
5. Other additive components of the examples and comparative examples include n-octylamine (5-1) and ethylene oxide (5-2).

The preparation and lithography experiment of the photoresist compositions of the examples and comparative examples are as follows:
A. resist preparation: according to different exposure doses and film thickness requirements, the formula of the photoresist composition was adjusted, and the photoresist composition was prepared according to the following solution: weighing a polymer resin, at least one photoacid generator and at least one dissolution inhibitor, dissolving in a solvent containing at least one component, stirring, and shaking until they are sufficiently dissolved, and filtering with a 0.22 μm film. Specifically, in the examples and comparative examples, the preparation was performed according to the components and addition amounts in Table 1, based on the solution composition for preparation of each 100 mL of photoresist composition.
B. lithography: spin-coating the mixed resist for 30 s at 3000 rpm/min to obtain a photoresist film layer with a thickness of 15-100 nm on the substrate (base plate); prebaking at 100° C. for 2 min; exposing by using an I-line 365 nm surface plasma lithography machine, through I-line 365 nm interference lithography or electron beam direct writing lithography method; post-baking at 100° C. for 1 min; and performing development with 2.83% TMAH for 30 s.

In the above, the sensitivity was defined as the exposure dose at which the photoresist film layer was completely removed after development; for optical lithography, the pattern was exposed at different doses by a light source with corresponding wavelengths and developed; for electron beam direct writing, the pattern was exposed at different doses by using a 20 KV electron beam; the thickness of the film layer in the exposure area after development was measured by a film layer/topography measuring instrument (such as an ellipsometer, an atomic force microscope, and a scanning electron microscope). The sensitivity of a value of 100 mJ/cm² or less or 100 μC/cm² or less is generally considered to be high sensitivity.

The film retention rate is the ratio of the thickness of the film layer in the non-exposure area after exposure and development (2.83% TMAH, 30 s) to the thickness of the resist film before exposure, where 95% or more indicates great, 80-95% indicates good, 50-80% indicates average, and 50% or less indicates poor; the thickness above was measured by a film layer/topography measuring instrument (e.g., an ellipsometer, an atomic force microscope, and a scanning electron microscope, etc.).

TABLE 1
Formulas and Lithography Results of Photoresist Compositions of Examples and Comparative Examples

| | | Photoacid | Dissolution | | Other | | | |
|---|---|---|---|---|---|---|---|---|
| | Resin | generator | inhibitor | | additive | | | |
| | and | and | and | | and | Film | | |
| | addition | addition | addition | Remaining | addition | retention | | Lithography |
| | amount | amount | amount | solvent | amount | rate | Sensitivity | method |
| Example 1 | 1-1-1 | 2-1 | 3-1 | 4-1 | 5-1 | Great | 25 | 365 nm |
| | (4 mg) | (0.5 mg) | (1 mg) | | (0.1 mg) | | mJ/cm² | SP |
| | | | | | | | | lithography |
| Example 2 | 1-1-1 | 2-1 | 3-1 | 4-1 | 5-1 | Great | 79 | 365 nm |
| | (4 mg) | (0.5 mg) | (0.1 mg) | | (0.1 mg) | | mJ/cm² | SP |
| | | | | | | | | lithography |
| Example 3 | 1-2-2 | 2-1 | 3-2 | 4-1 | | Good | 84 | 365 nm |
| | (4 mg) | (1 mg) | (0.1 mg) | | | | mJ/cm² | SP |
| | | | | | | | | lithography |
| Example 4 | 1-1-1 | 2-2 | 3-3 | 4-2 | 5-1 | Great | 10 | 365 nm |
| | (10 mg) | (5 mg) | (3 mg) | | (0.1 mg) | | mJ/cm² | proximity |
| | | | | | | | | lithography |
| Example 5 | 1-2-2 | 2-2 | 3-1 | 4-1 | 5-2 | Great | 50 | 365 nm |
| | (3 mg) | (0.5 mg) | (0.2 mg) | | (0.1 mg) | | mJ/cm² | interference |
| | | | | | | | | lithography |
| Example 6 | 1-3-1 | 2-2 | 3-2 | 4-2 | | Good | 36 | 365 nm |
| | (0.5 mg) | (0.1 mg) | (0.1 mg) | | | | mJ/cm² | interference |
| | | | | | | | | lithography |
| Example 7 | 1-1-1 | 2-3 | 3-4 | 4-3 | 5-2 | Great | 25 | 365 nm |
| | (3.5 mg) | (0.2 mg) | (2 mg) | | (0.1 mg) | | mJ/cm² | SP |
| | | | | | | | | lithography |
| Example 8 | 1-2-1 | 2-3 | 3-3 | 4-1 | | Great | 80 | 365 nm |
| | (5 mg) | (0.5 mg) | (0.2 mg) | | | | mJ/cm² | SP |
| | | | | | | | | lithography |
| Example 9 | 1-3-1 | 2-3 | 3-1 | 4-1 | | Great | 100 | 365 nm |
| | (5 mg) | (0.2 mg) | (0.1 mg) | | | | mJ/cm² | SP |
| | | | | | | | | lithography |
| Example 10 | 1-1-1 | 2-3 | 3-2 | 4-1 | | Great | 45 | 20 kV |
| | (5 mg) | (1 mg) | (1 mg) | | | | μC/cm² | electron |
| | | | | | | | | beam |
| Comparative | 1-1-1 | 2-1 | | 4-1 | 5-1 | Average | 130 | 365 nm |
| Example 1 | (4 mg) | (0.5 mg) | | | (0.1 mg) | | mJ/cm² | SP |
| | | | | | | | | lithography |
| Comparative | 1-2-1 | 2-1 | | 4-1 | | Poor | — | 365 nm |
| Example 2 | (4 mg) | (1 mg) | | | | | | SP |
| | | | | | | | | lithography |
| Comparative | 1-1-1 | 2-3 | | 4-1 | | Good | 115 | 20 kV |
| Example 3 | (5 mg) | (1 mg) | | | | | μC/cm² | electron |
| | | | | | | | | beam |

Example 1 is taken as an example for further explanation:

### Example 1

Polymer resin: 4 mg, the structural formula of the structural monomer is specifically:

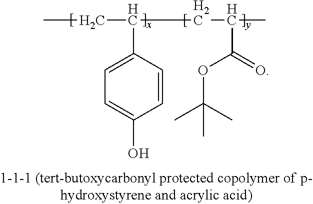 [SMILES: CCC(CC(C)C(=O)OC(C)(C)C)c1ccc(O)cc1]

Photoacid generator: 1 mg, the structural formula is specifically:

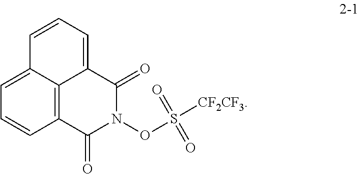

Dissolution inhibitor: 1 mg, the structural formula is specifically:

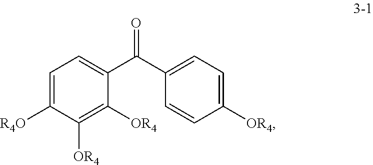

where one R₄ is H, and the other three R₄ are

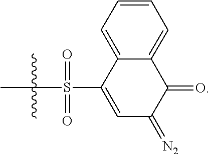

Other additive: n-octylamine; 0.1 mg.

Based on the preparation of each 100 mL of photoresist composition, the above components were added into the remaining propylene glycol methyl ether acetate solvent, the mixture was stirred and shaken until the components were fully dissolved, and filtered by using a 0.22 μm film. The lithography was performed according to the process conditions in the step B, and the film retention rate and the sensitivity were tested after the lithography was finished.

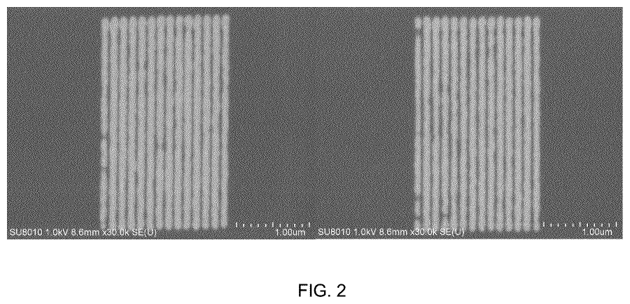

In Example 1, the I-line (365 nm) surface plasma lithography process was used, and the pattern period was: 128 nm. In this example, a film retention rate of greater than 95% is great, film layer quality is great, the contrast of the exposed 128 nm periodic grating pattern is great, the line edge roughness is less than 10 nm, and the exposure result pattern is shown in FIG. 2.

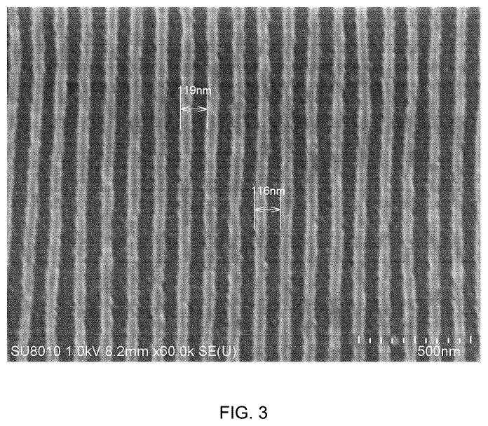

In Examples 2 to 10, experiments were performed by adjusting composition, content and/or lithography method separately, and the results were similar to those of Example 1. In the above, Example 4 used 365 nm proximity lithography, Examples 5 to 6 used 365 nm interference lithography, Example 10 and Comparative Example 3 used electron beam direct writing lithography, and the exposure pattern of Example 5 was as shown in FIG. 3, the film layer thickness was 40 nm, the pattern period was 120 nm, the film retention rate and sensitivity were great, the lines were clear and the contrast was great. By using the photoresist composition according to the present disclosure to perform high-resolution interference lithography, SP super-diffraction lithography, electron beam direct writing lithography, etc., great film retention rate and film quality can be achieved based on a thinner layer, preparation of high-quality dense line patterns with a size of less than 64 nm can be realized, and contrast and sensitivity are both high.

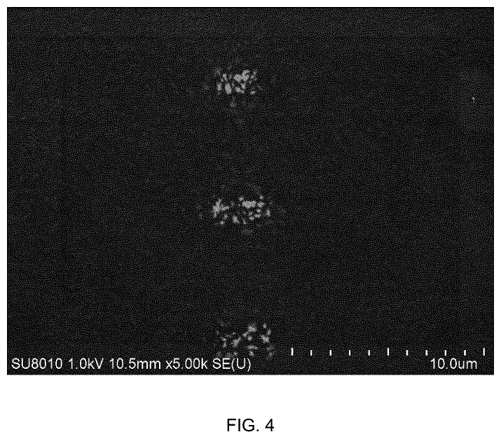

Example 2 and Comparative Example 1 are both control experiments of Example 1. In Example 2, only 0.1 mg of dissolution inhibitor was added, which is one tenth of that of Example 1, and other conditions were the same as those in Example 1, the sensitivity of the photoresist composition was changed from 25 mJ/cm² in Example 1 to 79 mJ/cm², having a significant deteriorating. While in Comparative Example 1, the dissolution inhibitor was further removed, the sensitivity of the photoresist composition was again deteriorated to 130 mJ/cm², the film retention rate was also significantly decreased, the exposure effect was very poor, no complete nanopattern was present, and the exposure result pattern of Comparative Example 1 is shown in FIG. 4.

Similarly, Comparative Example 3 is a control experiment of Example 10. In Comparative Example 3, the dissolution inhibitor was removed and the other conditions were the same as those in Example 10, the sensitivity of the photoresist composition was changed from 45 μC/cm² in Example 10 to 115 μC/cm², and the film retention rate was also decreased to some extent.

It can be seen that the design strategy of the photoresist composition proposed by the present disclosure, namely, the introduction of a functional dissolution inhibiting component based on DNQ molecules (containing DNQ groups) into a chemically amplified photoresist system, improves the overall lithographic performance. For ultrathin photoresist film layers, after the dissolution inhibitor in the present disclosure is used, the design requirements for film retention rate (i.e., hydrophobicity) of other components may be relaxed, and relatively more hydrophilic polymer resins and photoacid generators may be employed, and the lithographic performance thereof is optimized to the greatest extent. Further, by using the chemically amplified photoresist composition prepared by the active dissolution inhibiting components in the present disclosure, high-resolution lithography can be realized, and the prepared photoresist composition can be applied not only to existing lithography methods, but also to various novel high-resolution lithography techniques.

The objectives, technical solutions and beneficial effects of the present disclosure are further explained in detail with reference to the specific examples described above, and it should be understood that the above are merely specific examples of the present disclosure, and are not intended to limit the present disclosure. Any modification, equivalent substitution, improvement, and the like made within the spirit and principle of the present invention shall all fall within the protection scope of the present disclosure.

What is claimed is:

1. A photoresist composition, comprising:
a chemical amplification matrix, wherein the chemical amplification matrix comprises a polymer resin, a photoacid generator and a solvent, and the polymer resin is selected from the group consisting of p-hydroxystyrene resin, acrylate resin, and a resin obtained by copolymerizing p-hydroxystyrene monomers and acrylate monomers; and
a dissolution inhibitor, which is a small molecular material containing diazonaphthoquinone structures.

2. (canceled)

3. The photoresist composition according to claim 1, wherein the polymer resin contains repeating units of acid labile groups.

4. The photoresist composition according to claim 3, wherein the polymer resin has a molecular weight of 2000-100000; and the polymer resin is 0.5-10% by weight of the photoresist composition.

5. The photoresist composition according to claim 1, wherein the dissolution inhibitor is a molecule comprising a group containing 2 to 10 diazonaphthoquinone structures, with the group grafted in a form of sulfonate ester on a polyphenol backbone structure containing 2 to 10 phenolic hydroxyl groups.

6. The photoresist composition according to claim 5, wherein the dissolution inhibitor has a structure as shown in following formula III to formula VI: 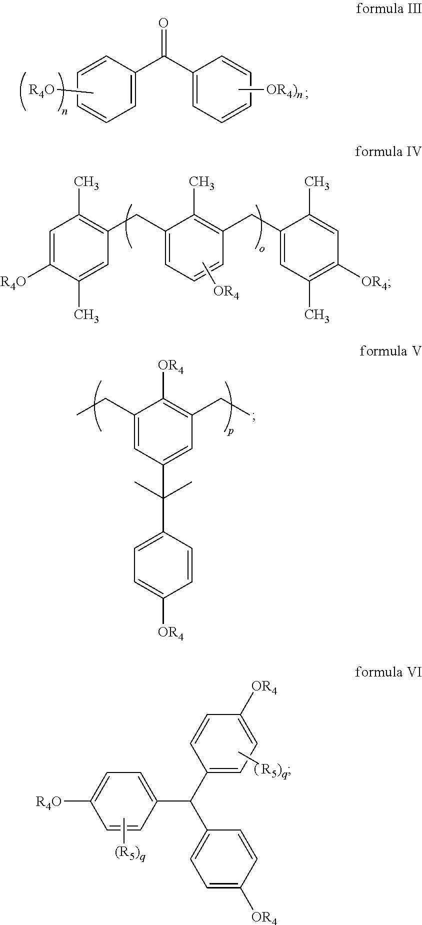
wherein R₄═H, 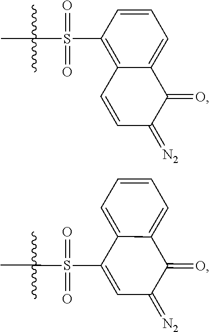
but not all R₄ are H; R₅=alkyl group having 1 to 5 carbon atoms; n=1-5; 0=1-10; p=1-10; and q=0-4.

7. The photoresist composition according to claim 6, wherein the dissolution inhibitor is 0.1% to 3% by weight of the photoresist composition.

8. The photoresist composition according to claim 1, wherein the photoacid generator is a compound of a nonionic sulfonate ester structure or an ionic onium salt structure; and
the photoacid generator is 0.1% to 5% by weight of the photoresist composition.

9. The photoresist composition according to claim 1, wherein the solvent comprises one of n-butyl acetate, ethyl acetate, γ-butyrolactone, propylene glycol methyl ether acetate, and propylene glycol methyl ether, or a mixture of more of them.

10. The photoresist composition according to claim 9, wherein the solvent is 80-99% by weight of the photoresist composition.

11. The photoresist composition according to claim 1, wherein the photoresist composition further comprises one of a leveling agent, a surfactant, and a stabilizer, or a mixture of more of them.

12. An application for using the photoresist composition according to claim 1, comprising using the photoresist composition in high-resolution interference lithography, SP super-diffraction lithography, electron beam direct writing, or I-line proximity lithography.
